(19) United States
(12) Patent Application Publication
(10) Pub. No.: US 2008/0211393 A1
(43) Pub. Date: Sep. 4, 2008

(54) LIGHT EMITTING APPARATUS

(76) Inventor: Hiroyuki YAEGASHI, Kanagawa (JP)

Correspondence Address: BIRCH STEWART KOLASCH & BIRCH, PO BOX 747, FALLS CHURCH, VA, 22040-0747, US

(21) Appl. No.: 12/022,863

(22) Filed: Jan. 30, 2008

(30) Foreign Application Priority Data
Feb. 2, 2007 (JP) 2007-024532

(51) Int. Cl. H01J 1/62

(52) U.S. Cl. 313/504

(57) ABSTRACT

A light emitting apparatus 10 having a substrate 12, a light emitting device 20 having: a pair of electrodes 14, 24 and an organic electroluminescent layer 18 disposed between the pair of electrodes that are stacked in the thickness direction on the substrate; lead-out lines 16, 26 formed on the substrate and respectively connected to the pair of electrodes of the light emitting device; an insulating layer 30 that contains an inorganic oxide and is formed on the substrate and on the lead-out lines and is formed around at least the light emitting device; an adhesive 32 provided on the insulating layer so as to surround the light emitting device, and a sealing member 34 that is bonded to the insulating layer via the adhesive and that seals the light emitting device.

### CROSS REFERENCE TO RELATED APPLICATION

This application claims priority under 35USC 119 from Japanese Patent Application No. 2007-24532, the disclosure of which is incorporated herein by reference.

### BACKGROUND OF THE INVENTION

1. Field of the Invention

The present invention relates to a light emitting apparatus, and more particularly to a light emitting apparatus using an organic electroluminescent device (organic EL device).

2. Description of the Related Art

Thin light emitting apparatuses using organic EL devices have recently been developed. FIG. 9 shows schematically the configuration of an organic EL device 1. An anode 3, an organic EL layer 8 (hole transport layer 4, emitting layer 5, and electron transport layer 6), a cathode 7, and the like are formed on a substrate 2 made of glass or the like. The apparatus is connected to external wiring via a lead-out line (terminal) 9, and when an electric field is applied to both electrodes 3, 7, the emitting layer 5 in the region sandwiched between the electrodes 3, 7 assumes an excited state and emits light.

Since the organic EL layer 8 has poor resistance to moisture and oxygen, the layer is sealed. For example, a method is used by which, as shown in FIG. 10, a sealing member 70 made of glass, metal, a resin film, or the like is bonded to the substrate 2 via an adhesive 72. The internal space of the sealing member 70 is filled with an inert gas, or a desiccant is provided therein, thereby making it possible to inhibit the deterioration of the organic EL device.

With regard to the substrate 2, in addition to a glass substrate, a resin film such as PET (polyethylene terephthalate) is sometimes used therefor. In the case of a resin substrate, it does not crack, unlike a glass substrate, even when bent to a large degree, and a display apparatus with a high shock resistance can be obtained. In particular, the advantages of using a resin substrate composed of a resin film also include high light transmittance and light weight.

However, moisture and oxygen generally easily pass through a resin film, thereby the deterioration of the organic EL layer is readily accelerated. Accordingly, a method has been suggested according to which the permeation of moisture and oxygen is prevented by providing an inorganic insulating film such as SiN or AlNxOy on the surface of a resin film (see Japanese Patent Application Laid-Open (JP-A) No. 2003-86356).

Regarding the sealing member 70, a sealing member has been suggested in which an insulating layer composed of a resin is laminated on a substrate having no gas permeability, such as a metal plate, in order to prevent the permeation of moisture and oxygen (see JP-A No. 2002-93573).

### SUMMARY OF THE INVENTION

The present invention has been made in view of the above circumstances and provides the below-described light emitting apparatus.

According to one aspect of the invention, there is provided a light emitting apparatus comprising a substrate, a light emitting device having a pair of electrodes and an organic electroluminescent layer disposed between the pair of electrodes that are stacked in the thickness direction on the substrate, lead-out lines formed on the substrate and respectively connected to the pair of electrodes of the light emitting device, an insulating layer that contains an inorganic oxide and is formed on the substrate and on the lead-out lines and is formed around at least the light emitting device, an adhesive provided on the insulating layer so as to surround the light emitting device, and a sealing member that is bonded to the insulating layer via the adhesive and that seals the light emitting device.

### BRIEF DESCRIPTION OF THE DRAWINGS

FIG. 1 is a schematic plan view illustrating an example (first embodiment) of the light emitting apparatus in accordance with the invention;

FIG. 2 is a schematic cross-sectional view along the A-A′ line in FIG. 1;

FIG. 3 is a schematic cross-sectional view along the B-B′ line in FIG. 1;

FIG. 4A is a schematic plan view illustrating an example of a layer that contains an inorganic oxide and is formed around a light emitting device;

FIG. 4B is a schematic plan view illustrating another example of a layer that contains an inorganic oxide and is formed around a light emitting device;

FIG. 4C is a schematic plan view illustrating yet another example of a layer that contains an inorganic oxide and is formed around a light emitting device;

FIG. 5 is a schematic cross-sectional view illustrating another example (second embodiment) of the light emitting apparatus in accordance with the invention;

FIG. 6 is a schematic cross-sectional view illustrating another example (third embodiment) of the light emitting apparatus in accordance with the invention;

FIG. 7 is a schematic cross-sectional view illustrating an example in which a moisture absorbent is provided in a space between a scaling member and a light emitting device;

FIG. 8 is a schematic cross-sectional view illustrating yet another example of the light emitting apparatus in accordance with the invention;

FIG. 9 is a schematic view illustrating an exemplary configuration of an organic EL device; and

FIG. 10 is a schematic cross-sectional view illustrating an example of the conventional light emitting apparatus.

### DETAILED DESCRIPTION OF THE INVENTION

The light emitting apparatus in accordance with the invention will be explained below with reference to the appended drawings.

The inventor has studied what causes deterioration of light emitting devices in light emitting apparatuses using organic electroluminescent devices (organic EL devices).

Typically, when a sealing member is adhered to a substrate, an ultraviolet radiation (UV) curable resin is coated on the adhesive surface of the substrate or sealing member, and the substrate and the sealing member are superposed on each other and adhered by irradiating them with UV radiation. The inventor has found that due to insufficient adhesive force, in particular, at the adhesive interface of the substrate and the adhesive, moisture and oxygen present in the atmosphere penetrate to the interior of the sealing member and accelerate the deterioration of the device. In particular as shown in FIG. 10, when a sealing member 70 is adhered thereto so that a space is provided between the sealing member 70 and the organic EL device, while the deterioration of the device can be effectively prevented by filling the space with an inert gas or providing a desiccant, the adhesive force is insufficient and moisture and oxygen readily penetrate into the space because the bonded surface of the sealing member 70 and the substrate 2 is small.

It was assumed that this insufficient adhesive force was related to wettability of the adhesive surface when the adhesive was coated thereon, and it was found that a high adhesive force could be obtained when the adhesive surface had hydrophilicity.

When a non-alkali glass is used as the substrate, it can be rendered hydrophilic by surface treatment. On the other hand, when the substrate is made of a film material such as polyethylene naphthalate (PEN), while the substrate surface is hydrophobic, wettability can be improved by forming an inorganic insulating film called a barrier layer on the substrate surface.

However, as shown in FIG. 10 places where a lead-out line 9 is formed are present in the bonded portion on the substrate 2, and the sealing member 70 is also adhered to the lead-out line 9 located on the substrate 2 via an adhesive layer 72. For example, when the lead-out line 9 is formed of a metal film in consideration of resistance of electrode, in some usage environments, the lead-out line 9 is corroded by the influence of moisture or the like contained in the atmosphere. If the corrosion advances, the interface with the adhesive 72 peels off, thereby facilitating the penetration of moister or the like from the air and accelerating the deterioration of the organic EL device.

The inventor has found that the adhesive force can be increased and the penetration of moisture and oxygen contained in the atmosphere from the bonded portion can be prevented by forming an insulating layer containing an inorganic oxide around the light emitting device located on a substrate, which serves as an adhesive portion with a sealing member, after the light emitting device, lead-out line, and the like have been formed, and providing an adhesive between the insulating layer containing the inorganic oxide and the sealing material to adhere them. This finding led to completion of the invention.

### FIRST EMBODIMENT

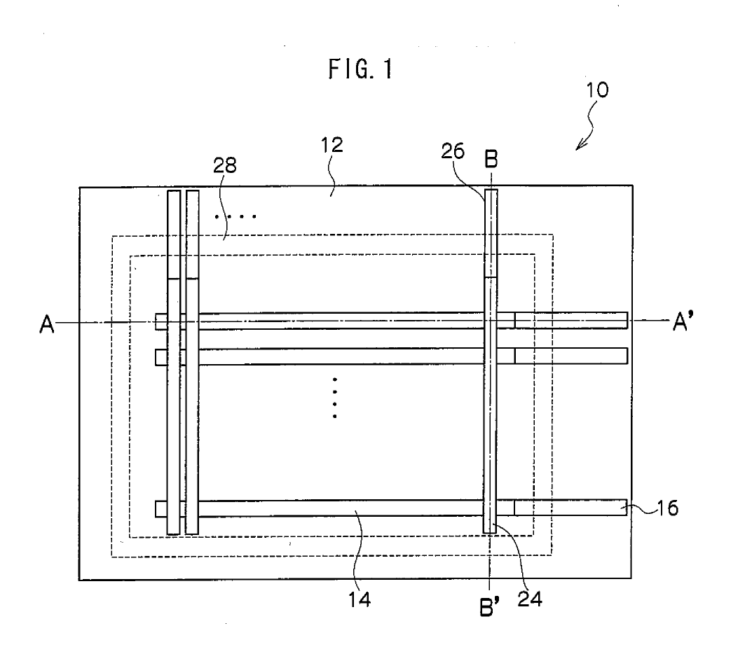

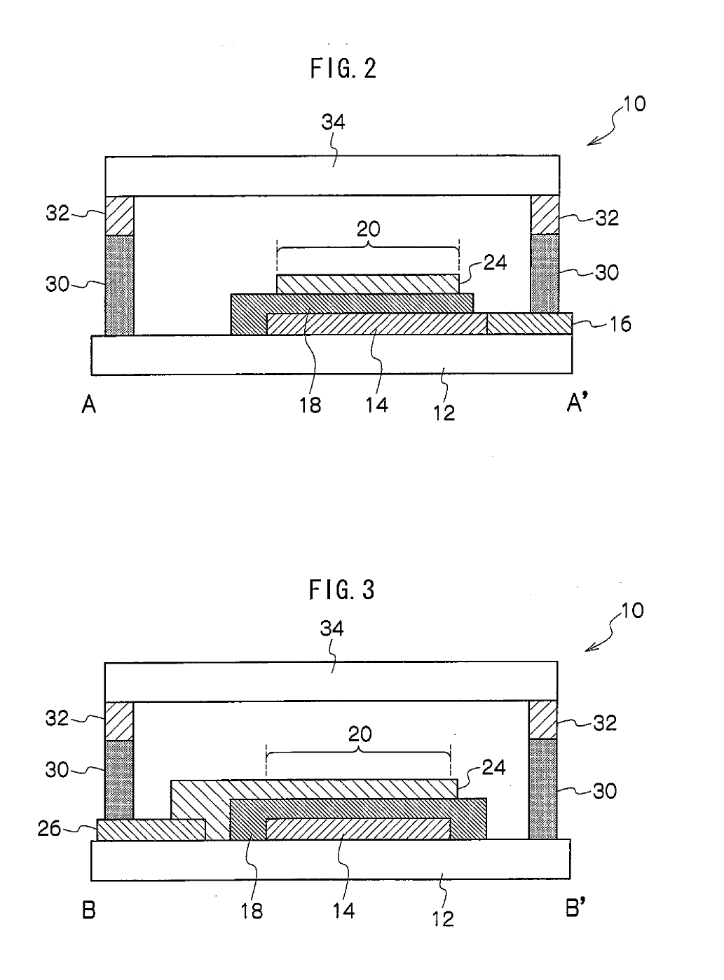

FIG. 1 is a schematic plan view illustrating an example of the light emitting apparatus in accordance with the invention. FIG. 2 is a schematic cross-sectional view along the A-A′ line of the light emitting apparatus shown in FIG. 1. FIG. 3 is a schematic cross-sectional view along the B-B′ line. As shown in FIG. 1, an anode 14 and a cathode 24 are each formed as a stripe, but in FIG. 2 and FIG. 3, the electrodes 14, 24 are shown simply as an integral configuration and partitions and the like are omitted.

The light emitting apparatus 10 is of a passive matrix type in which light emitting devices 20 are arranged in electrical intersections of data lines and scan lines. As shown in FIG. 1, on a substrate 12, a pair of electrodes 14, 24 composed of the anode 14 and cathode 24 are arranged in the form of a matrix (some of the electrodes are omitted in the fig), and the lead-out lines 16, 26 that are connected to respective electrodes 14, 24 are formed. Here, the electrodes 14, 24 function as a data line and a scan line, respectively, or as a scan line and a data line, respectively. Further, as shown in FIG. 2 and FIG. 3, the anode 14 and cathode 24 are stacked in the thickness direction of the substrate 12, and an organic electroluminescent layer (organic EL layer) 18 is formed between the pair of electrodes 14, 24. The pair of electrodes 14, 24 and the organic EL layer 18 formed in a portion where the electrodes 14, 24 intersect constitute an organic EL device, that is, a light emitting device 20 that emits light.

An insulating layer 30 containing an inorganic oxide is formed in a region 28 where the sealing member 34 is adhered around the light emitting device 20 located on the substrate 12. This layer 30 is also formed on the lead-out lines 16, 26. A plate-like sealing member 34 for sealing the light emitting device 20 is adhered via the adhesive 32 provided between the sealing member 34 and the insulating layer 30 containing the inorganic oxide on the substrate 12. With such a configuration, the adhesive force between the adhesive and the insulating layer 30 that contains the inorganic oxide and is formed around the light emitting device 20 located on the substrate 12 is enhanced, and the penetration of oxygen and moisture in the bonded portion of the sealing member 34 and the substrate 12 is substantially inhibited.

The configuration and the like of the light emitting apparatus in accordance with the invention will be described below in greater detail together with the method for manufacture thereof.

### <Substrate>

The substrate 12 is not particularly limited, provided that it has strength sufficient to support the organic EL device and the like and also light transmittance, and a well-known substrate can be used. For example, in the case of a light emitting apparatus of so-called bottom emission type in which light is transmitted from the side of the substrate 12, a substrate that does not scatter or attenuate the light emitted from the emitting layer as much as possible is preferred. Specific examples of such substrates include inorganic materials such as Yttria-Stabilized Zirconia (YSZ) and glass, and organic materials such as polyester, e.g. polyethylene terephthalate, polybutylene phthalate, and polyethylene naphthalate, and also polystyrene, polycarbonate, polyether sulfone, polyacrylate, polyimide, polycycloolefin, norbornene resins, and poly(chlorotrifluoroethylene).

For example, when glass is used as the substrate 12, a non-alkali glass is preferred to reduce elution of ions from the glass. When soda lime glass is used, it is preferred that a barrier coat such as silica be provided on the glass.

Further, when a substrate made of organic material is used, it is preferred that the substrate is excellent in terms of heat resistance, dimensional stability, resistance to solvents, electrical insulating properties, and processability. In particular, when a plastic substrate is used, it is preferred that a moisture permeation preventing layer or a gas barrier layer be provided on one surface or both surfaces of the substrate to inhibit the permeation of moisture or oxygen. Inorganic substances such as silicon nitride and silicon oxide can be advantageously used as materials for the moisture permeation preventing layer or gas barrier layer. The moisture permeation preventing layer or gas barrier layer can be formed, for example, by a high-frequency sputtering method.

When a thermoplastic substrate is used, it may be further provided, if necessary, with a hard coat layer, an undercoat layer, or the like.

The shape, structure, and size of the substrate 12 are not particularly limited and can be appropriately selected according to the application, object, and the like of the light emitting apparatus. Generally, from the standpoint of handleability and easiness of forming the light emitting device 20, it is preferred that the substrate 12 have a plate-like shape. The structure of the substrate 12 may be a monolayer structure or a laminated structure. Further, the substrate 12 may be configured of a single member or be composed of two or more members.

The substrate 12 may be colorless and transparent or colored and transparent, but from the standpoint of enabling the prevention of scattering and attenuation of the light emitted from the light emitting device 20, it is preferred that the substrate be colorless and transparent.

### <Organic EL Device>

The organic EL device 20 is formed as a light emitting device on the substrate 12. The layer structure of the light emitting device 20 in accordance with the invention is not particularly limited, provided that the light emitting device has the organic EL layer 18 between a pair of electrodes 14, 24 that includes the anode 14 and the cathode 24 laminated in the thickness direction of the substrate 12. Specific examples of the layer structure are listed below. However, in the invention, the layer structure is not limited to these structures and the layer structure of the light emitting device can be appropriately determined according to the object or the like.

Anode/Emitting layer/Cathode.

Anode/Hole transport layer/Emitting layer/Electron transport layer/Cathode.

Anode/Hole transport layer/Emitting layer/Blocking layer/Electron transport layer/Cathode.

Anode/Hole transport layer/Emitting layer/Blocking layer/Electron transport layer/Electron injection layer/Cathode.

Anode/Hole injection layer/Hole transport layer/Emitting layer/Blocking layer/Electron transport layer/Cathode.

Anode/Hole injection layer/Hole transport layer/Emitting layer/Blocking layer/Electron transport layer/Electron injection layer/Cathode.

### <Anode and Lead-Out Line>

As shown in FIG. 1 and FIG. 2, the anode 14 is formed as a stripe on the substrate 12, and the lead-out line 16 is connected to one end of the anode.

The shape, structure, and size of the anode 14 are not particularly limited and can be appropriately selected from those of well-known electrode materials according to the application, object or the like of the light emitting apparatus, provided that the anode have a function of an electrode for supplying holes to the organic EL layer 18. However, from the standpoint of properties of the light emitting device, it is preferred that at least one electrode of the anode 14 and the cathode 24 be transparent; usually, the transparent anode 14 is formed.

Examples of materials that can be advantageously used for constituting the anode 14 include metals, alloys, metal oxides, electrically conductive compounds, or mixtures thereof. Specific examples include electrically conductive metal oxides such as tin oxide doped with antimony, fluorine, or the like (ATO, FTO), tin oxide, zinc oxide, indium oxide, indium tin oxide (ITO), and indium zinc oxide (IZO); metals such as gold, silver, chromium, and nickel; mixtures or laminates of these metals and electrically conductive metal oxides; inorganic conductive substances such as copper iodide and copper sulfide; organic conductive materials such as polyaniline, polythiophene, and polypyrrole; and laminates of these and ITO. The preferred among them are electrically conductive metal oxides, and from the standpoint of productivity, high conductivity, transparency, and the like, ITO is especially preferred.

Examples of methods suitable for forming the anode 14 include wet methods such as printing and coating, physical methods such as vacuum deposition, sputtering, and ion plating, and chemical methods such as CVD and plasma CVD. The anode 14 can be formed on the substrate 12 by a method that is appropriately selected with consideration of compatibility with the material for forming the anode 14. For example, when ITO is selected as the anode material, the anode 14 can be formed by DC or high-frequency sputtering, vacuum deposition, ion plating, or the like.

The position for forming the anode 14 is not particularly limited and can be appropriately selected according to the application, object or the like of the light emitting apparatus. Thus, the anode 14 may be formed on the whole of one of the surfaces of the substrate 12 or may be partially formed thereon

Patterning in the formation of the anode 14 may be performed by chemical etching based on photolithography or the like or by physical etching employing a laser or the like. Further, vacuum deposition, sputtering or the like may be performed using a mask, or the patterning may be performed by a lift-off method or a printing method.

The lead-out line 16 for the anode can be formed by the same method and using the same material as those employed to form the anode 14, and the lead-out line to be connected to the anode 14 may be formed simultaneously with the formation of the anode 14. Where the operations of patterning the anode 14 and the lead-out line 16 for the anode are performed simultaneously, the number of process steps can be reduced and lead-out lines 16 reliably connected to each anode 14 can be formed. In this process, the lead-out line 26 for the cathode may be formed at the same time.

The thickness of the anode 14 and the lead-out line 16 can be appropriately selected according to the material constituting the anode 14 and the like and cannot be determined uniquely. Usually, the thickness is about 10 nm to 50 μm, preferably 50 nm to 20 μm.

Further, the electric resistance of the anode 14 and lead-out line 16 is preferably 10³Ω/□ or less, more preferably 10²Ω/□ or less in order to supply holes reliably to the organic EL layer 18.

When the transparent anode 14 is employed, it may be colorless and transparent or colored and transparent. In order to take out light from the transparent anode side, the light transmittance of the anode is preferably 60% or more, more preferably 70% or more. Transparent anodes are explained in detail in “New Development of Transparent Electrode Film”, supervised by Yutaka Sawada, published by CMC (1999), and matters described therein can be also applied to the invention. For example, when a plastic substrate with a low heat resistance is used, a transparent anode using ITO or IZO and deposited at a low temperature of 150° C. or less is preferred.

### <Organic EL Layer>

The light emitting device 20 has the organic EL layer 18 containing at least an emitting layer between the anode 14 and the cathode 24. Examples of layers other than the emitting layer that constitute the organic EL layer 18 include, as described hereinabove, a hole transport layer, an electron transport layer, a charge blocking layer, a hole injection layer, and an electron injection layer. In a preferred layer structure, a hole transport layer, an emitting layer, and an electron transport layer are laminated in the order of description from the anode side. Further, a charge blocking layer and the like may be present, for example, between the hole transport layer and the emitting layer or between the emitting layer and the electron transport layer. A hole injection layer may be present between the anode and the hole transport layer, and an electron injection layer may be present between the cathode and the electron transport layer. Further, each layer may be divided into plural secondary layers.

Each of these layers constituting the organic EL layer 1S can be advantageously formed by a dry deposition method such as vapor deposition and sputtering, or by a transfer method, a printing method, and the like.

### —Emitting Layer—

The emitting layer has a function of receiving holes from the anode, hole injection layer, or hole transport layer and receiving electrons from the cathode, electron injection layer, or electron transport layer when an electric field is applied thereto, providing sites for recombination of the holes and electrons, and emitting light.

The emitting layer may be made up of only an emitting material, or may be made up as a layer of mixture of a host material and an emitting material. Further, the emitting layer may also contain a material that has no charge transport capability and does not emit light. The emitting layer may include one layer or two or more layers, and each layer may emit light of different color.

The emitting material may be a fluorescence emitting material or a phosphorescence emitting material, and may be doped with one or two or more dopants.

Examples of fluorescence emitting material include a variety of metal complexes represented by metal complexes of benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, condensation aromatic compounds, perynone derivatives, oxadiazole derivatives, oxazine derivatives, aldazine derivatives, pyralidine derivatives, cyclopentadiene derivatives, bis-styrylanthracene derivatives, quinacridone derivatives, pyrrolopyridine derivatives, thiadiazolopyridine derivatives, cyclopentadiene derivatives, styrylamine derivatives, diketopyrrolopyrrole derivatives, aromatic dimethylidine derivatives, and 8-quinolinol derivatives and metal complexes of pyrromethene derivatives; polymer compounds such as polythiophene, polyphenylene, and polyphenylene vinylene; and compounds of organosilane derivatives.

Examples of phosphorescence emitting materials include complexes containing a transition metal atom or a lanthanoid atom.

Transition metal atoms are not particularly limited, the preferred examples thereof including ruthenium, rhodium, palladium, tungsten, rhenium, osmium, iridium, and platinum and more preferred examples including rhenium, iridium, and platinum.

Examples of lanthanoid atoms include lanthanum, cerium, praseodymium, neodymium, samarium, europium, gadolinium, terbium, dysprosium, holmium, erbium, thulium, ytterbium, and lutetium. Among these lanthanoid atoms, neodymium, europium, and gadolinium are preferred.

Examples of ligands of the complexes are described in G. Wilkinson et al., “Comprehensive Coordination Chemistry”, Pergamon Press Co., published in 1987; H. Yersin, “Photochemistry and Photophysics of Coordination Compounds”, Springer-Verlag, published in 1987; Akio Yamamoto “Organic metal chemistry—basic and application—”, Shokabo Publishing Co., Ltd., published in 1982; and the like.

Specific examples of preferred ligands include halogen ligands (preferably chlorine ligand), nitrogen-containing heterocyclic ligands (for example, phenylpyridine, benzoquinoline, quinolinol, bipyridyl, and phenanthroline), diketone ligands (for example, acetylacetone), carboxylic acid ligands (for example, acetic acid ligand), carbon monoxide ligand, isonitrile ligand, and cyano ligand; among them, nitrogen-containing heterocyclic ligands are more preferred. The above-described complexes may have one transition metal atom in a compound or may be the so-called dinuclear complexes that have two or more transition metal atoms. Dissimilar metal atoms may be contained simultaneously.

The phosphorescence emitting material is contained in the emitting layer preferably at 0.1 to 40% by mass, more preferably at 0.5 to 20% by mass.

The host material contained in the emitting layer is preferably a charge transporting material. The host material of one kind or host materials of two or more kinds may be employed. For example, a composition can be used in which a host material with electron transport ability and a host material with a hole transport ability is mixed.

Specific examples of host materials include materials having a carbazole skeleton, a diarylamine skeleton, a pyridine skeleton, a pyrazine skeleton, a triazine skeleton, and an arylsilane skeleton, or materials listed in the below-described sections relating to the hole injection layer, the hole transport layer, the electron injection layer, and the electron transport layer.

The thickness of the emitting layer is not particularly limited, and usually the thickness is preferably 1 nm to 500 nm, more preferably 5 nm to 200 nm, and even more preferably 10 nm to 100 nm.

### —Hole Injection Layer and Hole Transport Layer—

The hole injection layer and the hole transport layer function to receive holes from the anode 14 or anode side and transport the holes to the cathode side. The hole injection layer and the hole transport layer preferably contain any of metal complexes of various kinds represented by Ir complexes having as a ligand a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidine compound, a porphyrin compound, an organosilane compound, carbon, phenylazole, or phenylazine.

From the standpoint of lowering the driving voltage, it is preferred that the thickness of the hole injection layer and the hole transport layer be 500 nm or less for each layer.

The thickness of the hole transport layer is preferably 1 nm to 500 nm, more preferably 5 nm to 200 nm, and even more preferably 10 nm to 200 nm. The thickness of the hole injection layer is preferably 0.1 nm to 200 nm, more preferably 0.5 nm to 200 nm, and even more preferably 1 nm to 200 nm.

Each of the hole injection layer and the hole transport layer may have a monolayer structure comprising one, or two or more of the above-described materials, or a multilayer structure comprising plural layers of identical or dissimilar compositions.

### —Electron Injection Layer and Electron Transport Layer—

The electron injection layer and the electron transport layer function to receive electrons from the cathode 24 or cathode side and transport the electrons to the anode side. Specifically, the hole injection layer and the hole transport layer preferably contain any of metal complexes of various kinds represented by a metal complex of a triazole derivative, an oxazole derivative, an oxadiazole derivative, an imidazole derivative, a fluorenone derivative, an anthraquinodimethane derivative, an anthrone derivative, a diphenylquinone derivative, a thiopyrandioxide derivative, a carbodiimido derivative, a fluorenylidenemethane derivative, a distyrylpyrazine derivative, an aromatic tetracarboxylic acid anhydride such as naphthalene and perylene, a phthalocyanine derivative, and an 8-quinolinol derivative, and a metal complex having a metal phthalocyanine, benzoxazole, or benzothiazole as a ligand, and an organosilane derivative.

From the standpoint of lowering the driving voltage, it is preferred that the thickness of the electron injection layer and the electron transport layer be 500 nm or less for each layer.

The thickness of the electron transport layer is preferably 1 nm to 500 nm, more preferably 5 nm to 200 nm, and even more preferably 10 to 100 nm. The thickness of the electron injection layer is preferably 0.1 nm to 200 nm, more preferably 0.2 nm to 100 nm, and even more preferably 0.5 nm to 50 nm.

Each of the electron injection layer and the electron transport layer may have a monolayer structure comprising one, or two or more of the above-described materials, or a multilayer structure comprising plural layers of identical or dissimilar compositions.

### —Hole Blocking Layer—

The hole blocking layer has a function of preventing the holes that have been transported from the anode side to the emitting layer from penetrating to the cathode side. The hole blocking layers adjacent to the emitting layer at the cathode side thereof can be provided.

Examples of organic compounds for constituting the hole blocking layer include aluminum complexes such as BAlq, triazole derivatives, and phenanthroline derivatives such as BCP, and the like.

The thickness of the hole blocking layer is preferably 1 mm to 500 nm, more preferably 5 nm to 200 nm, and even more preferably 10 nm to 100 nm.

The hole blocking layer may have a monolayer structure comprising one, or two or more of the above-described materials, or a multilayer structure comprising plural layers of identical or dissimilar compositions.

### <Cathode and Lead-Out Line>

The cathode 24 is formed as a stripe on the organic EL layer 18 so as to intersect with the anode 14.

Usually, the cathode 24 has a function of an electrode for supplying electrons to the organic EL layer 18 and shape, structure, and size of the cathode 24 are not particularly limited and can be appropriately selected from those of the well-known electrode materials according to the application, object or the like of the light emitting apparatus. Examples of materials for constituting the cathode 24 include metals, alloys, metal oxides, electrically conductive compounds, and mixtures thereof. Specific examples include alkali metals (for example, Li, Na, K, Cs and the like), alkaline earth metals (for example, Mg, Ca and the like), gold, silver, lead, aluminum, sodium-potassium alloys, lithium-aluminum alloys, magnesium-silver alloys, indium, rare earth metals such as ytterbium, and the like. These materials may be used individually, but from the standpoint of improving both the stability and the electron injection ability, two or more thereof can be advantageously used together.

Among the above-mentioned materials for constituting the cathode 24, from the standpoint of electron injection ability, alkali metals and alkaline earth metals are preferred, and from the standpoint of excellent stability in storage, materials containing aluminum as the main component are preferred. Examples of materials containing aluminum as the main component include pure aluminum, alloys of aluminum and 0.01 to 10% by mass an alkali metal or alkaline earth metal, and mixtures thereof (for example, lithium-aluminum alloys, magnesium-aluminum alloys and the like).

Materials for the cathode 24 are explained in detail in JP-A Nos. 2-15595 and 5-121172, and the materials described in these open publications can be also applied to the invention.

The method for forming the cathode 24 is not particularly limited and the cathode 24 can be formed according to well-known methods. For example, the cathode 24 can be formed by a method that is appropriately selected with consideration of compatibility with the material for forming the cathode from among wet methods such as printing and coating, physical methods such vacuum deposition, sputtering, and ion plating, and chemical methods such as CVD and plasma CVD. For example, when a metal or the like is selected as the cathode material, the cathode can be formed by sputtering one metal, or two or more metals in a simultaneous or consecutive mode.

Patterning in the formation of the cathode 24 may be performed by chemical etching based on photolithography or the like or by physical etching employing a laser or the like. Further, vacuum deposition or sputtering may be performed using a mask, or the patterning may be performed by a lift-off method or a printing method.

The lead-out line 26 for the cathode can be formed by the same method and using the same material as those used to form the cathode 24, but the lead-out line 26 can be also formed simultaneously with the formation of the cathode 24. Where the operations of patterning the cathode 24 and the lead-out line 26 for the cathode are performed simultaneously, the number of process steps can be reduced and lead-out lines 26 reliably connected to each cathode 24 can be formed.

The formation position of the cathode 24 is not particularly limited and the cathode 24 may be formed on the whole of the organic EL layer 18 or may be partially formed thereon.

A dielectric layer composed of an alkali metal or alkaline earth metal fluorides, oxides, and the like may be formed to have a thickness of 0.1 nm to 5 nm between the cathode 24 and the organic EL layer 18. The dielectric layer can be also considered as a kind of an electron injection layer. The dielectric layer can be formed, for example, by vacuum deposition, sputtering, ion plating or the like.

The thickness of the cathode 24 can be appropriately selected according to the material constituting the cathode 24 and cannot be determined uniquely. Usually, the thickness is about 10 nm to 5 μm, preferably 50 nm to 1 μm.

The cathode 24 may be transparent or opaque. In the case of the transparent cathode 24, a thin film with a thickness of 1 nm to 10 nm is formed using the material for the cathode 24 and the cathode 24 can be formed by laminating thereon a transparent electrically conductive material such as ITO and IZO in particular.

### <Protective Layer>

The light emitting device 20 may be protected with a protective layer. A material having a function of inhibiting the penetration of substances accelerating deterioration of the device, such as moisture and oxygen, into the device can be used as a material constituting the protective layer. Specific examples include metals such as In, Sn, Pb, Au, Cu, Ag, Al, Ti, and Ni, metal oxides such as MgO, SiO, SiO₂, Al₂O₃, GeO, NiO, CaO, BaO, Fe₂O₃, Y₂O₃, and TiO₂, metal nitrides such as SiNₓ, and SiNₓO_{y}, metal fluorides such as MgF₂, LiF, AlF₃, and CaF₂, polyethylene, polypropylene, poly(methyl methacrylate), polyimides, polyurea, polytetrafluoroethylene, polychlorotrifluoroethylene, polydichlorodifluoroethylene, a copolymer of chlorotrifluoroethylene and dichlorodifluoroethylene, copolymers obtained by copolymerizing a monomer mixture containing tetrafluoroethylene and at least one comonomer, fluorine-containing copolymers having a cyclic structure in the main chain of copolymerization, hygroscopic substances with a hygroscopicity of 1% or more, and moisture-proof substances with a hygroscopicity of 0.1% or less.

The method for forming the protective layer is not particularly limited, and the examples of methods that can be applied include vacuum deposition, sputtering, reactive sputtering, MBE (molecular beam epitaxy), cluster ion beam, ion plating, plasma polymerization (high-frequency excitation ion plating), plasma CVD, laser CVD, thermal CVD, gas source CVD, coating, printing, and transferring.

### <Insulating Layer Containing Inorganic Oxide>

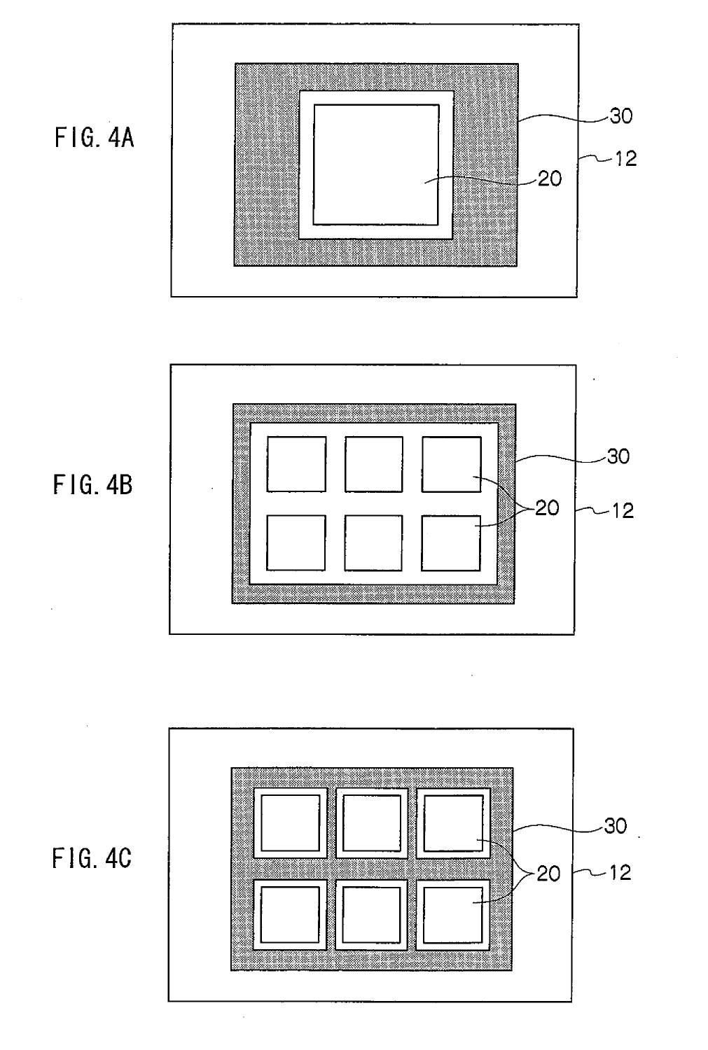

An insulating layer 30 containing an inorganic oxide is formed around the light emitting device 20 after the light emitting device 20, lead-out lines 16, 26 and the like have been formed on the substrate 12. FIGS. 4A to 4C show schematically examples of the insulating layer 30 containing the inorganic oxide and formed around the light emitting device 20. When one light emitting device 20 is formed on the substrate 12, the insulating layer 30 containing the inorganic oxide is formed around the light emitting device 20 (FIG. 4A). On the other hand, when plural light emitting devices 20 are formed on the substrate 12, the insulating layer is usually formed so as to surround the entire region where the light emitting devices 20 have been formed (FIG. 4B), but the insulating layer 30 may be also formed around each light emitting device 20 individually (FIG. 4C). In either case, the insulating layer 30 containing the inorganic oxide is formed in the region around the light emitting device 20 to which a sealing member 34 will be bonded via an adhesive.

Examples of inorganic oxides contained in the layer 30 include SiO, SiO₂, SiNxOy and the like. The higher the proportion of the inorganic oxide in the layer 30, the better, and it is even more preferred that the layer be composed entirely of inorganic oxide.

Examples of methods for forming such an insulating layer 30 containing an inorganic oxide include sputtering, reactive sputtering, MBE (molecular beam epitaxy), cluster ion beam, ion plating, plasma polymerization (high-frequency excitation ion plating), plasma CVD, etc. The insulating layer 30 containing the inorganic oxide is usually formed in a position around the light emitting device where the adhesive will be coated, but because elongation sometimes occurs, especially, when a plastic substrate or a plastic sealing member is used, the insulating layer is preferably formed with consideration of such elongation of the substrate or sealing member.

The thickness of the layer 30 containing the inorganic oxide depends on the shape and the like of the sealing member 34 that will be bonded thereto, but in order to ensure a high adhesive force between the insulating layer 30 and the sealing member 34 and to ensure a proper space between the sealing member 34 and the light emitting device 20, it is preferred that the thickness be 1 nm to 10 μm, more preferably 100 nm to 5 μm.

By thus forming the insulating layer 30 containing the inorganic oxide around the light emitting device 20, in the portion around the light emitting device 20 where the lead-out lines 16, 26 have not been formed, the insulating layer 30 containing the inorganic oxide is formed on the surface of the substrate 12, whereas in the portion where the lead-out lines 16, 26 have been formed, the insulating layer 30 containing the inorganic oxide is formed on the lead-out lines 16, 26, as shown in FIG. 2 and FIG. 3.

### <Sealing>

After the layer 30 containing the inorganic oxide has been formed around the light emitting device 20, the adhesive 32 is applied between the layer 30 containing the inorganic oxide and the sealing member 34 and the two are bonded together.

The material of the sealing member 34 is not particularly limited, and the sealing member 34 composed of a well-known material such as glass, a metal, and a resin film can be used.

On the other hand, well-known materials that have been used for bonding the sealing member 34 can be used as the adhesive 32. For example, XNR-5516 manufactured by Nagase ChemteX Corp. and the like can be used from among the UV-curable resins.

For example, a UV-curable resin is coated on the insulating layer 30 containing the inorganic oxide that has been formed around the light emitting device 20, the sealing member 34 is superposed thereon, and bonding is performed by irradiation with UV radiation. Alternatively, a UV-curable resin is coated on the portion of the sealing member 34 that will be bonded, and the sealing member 34 is superposed on and bonded to the insulating layer 30 containing the inorganic oxide and located on the substrate 12. In either case, the adhesive 32 is provided between the sealing member 34 and the insulating layer 30 containing the inorganic oxide and formed around the light emitting device 20 on the substrate 12, and the sealing member 34 is bonded via the adhesive 32. As a result, the insulating layer 30 containing the inorganic oxide is also formed on the lead-out lines 16, 26 in the portion where the sealing member 34 will be bonded on the substrate 12. Therefore, the adhesivity of the adhesive 32 increases, and the sealing member 34 is strongly bonded via the adhesive 32 to the insulating layer 30 containing the inorganic oxide and located on the substrate 12. By adjusting the thickness of the adhesive 32 or the insulating layer 30 containing the inorganic oxide that is formed around the light emitting device 20 on the substrate 12 and providing a space between the sealing member 34 and the light emitting device 20, it is also possible to enclose a desiccant, an inert gas, an inert liquid, or the like.

The light emitting device (organic EL device) 20 can be caused to emit light by connecting respective external wirings (not shown in the figures) to the lead-out lines 16, 26 and applying a DC (if necessary, may also contain an AC component) voltage (usually 2 V to 15 V) or a DC current between the anode 14 and the cathode 24. Driving methods described in the specifications of JP-A Nos. 2-148687, 6-301355, 5-29080, 7-134558, 8-234685, and 8-241047, Japanese Patent No. 2784615, and U.S. Pat. Nos. 5,828,429 and 6,023,308, and the like can be applied to drive the light emitting device 20.

The above-described process makes it possible to manufacture a light emitting apparatus 10 in which the sealing member 34 is bonded to the insulating layer 30 containing the inorganic oxide that is formed around the light emitting device 20 via the adhesive 32 provided between the sealing member 34 and the insulating layer 30. With the light emitting apparatus 10 thus manufactured, it is possible to prevent effectively the oxygen or moisture contained in the atmosphere from penetrating through the bonded portion of the sealing member 34 and the substrate 12, thereby greatly inhibiting the degeneration of luminescent pixels and deterioration of the electrodes, organic EL layer, and the like, and extending the service life.

### SECOND EMBODIMENT

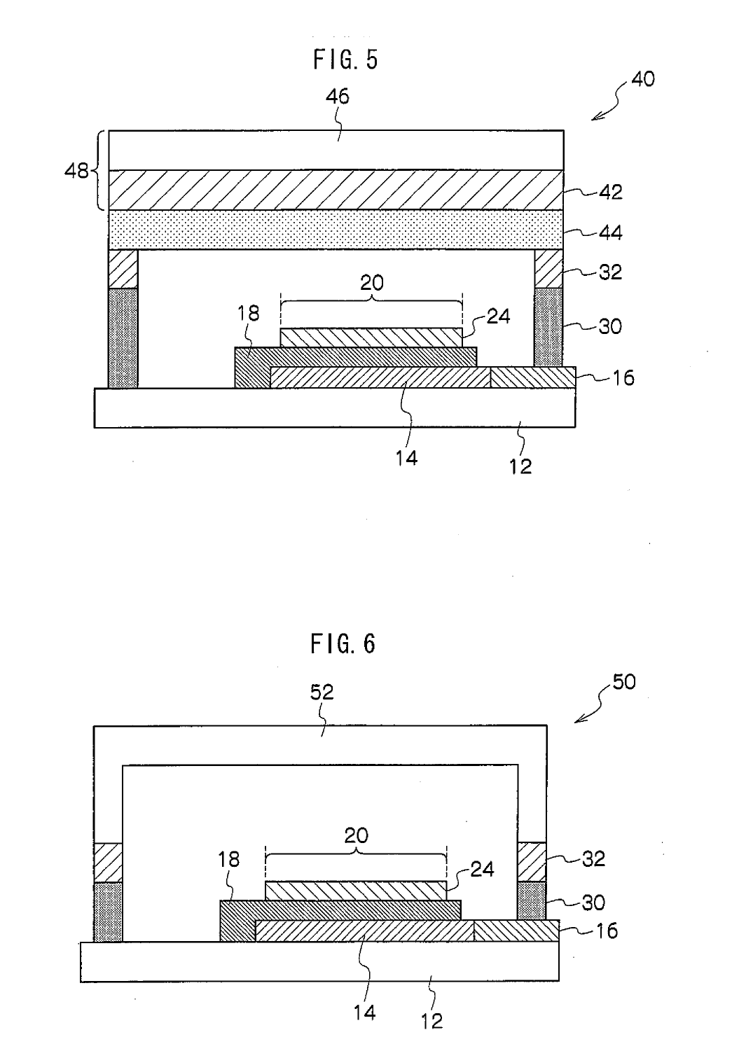

FIG. 5 shows schematically a cross-section of the second embodiment of the light emitting apparatus in accordance with the invention. In this light emitting apparatus 40, a sealing member 48 is used in which a barrier layer 42 for preventing the penetration of oxygen or moisture contained in the atmosphere is formed on one surface of a plastic base material 46. By providing such a barrier layer 42, it is possible to significantly inhibit the transmission of moisture or the like through the sealing member 48.

An inorganic oxide insulating film 44 is further formed on the side of the barrier layer 42 of the sealing member 48, an adhesive 32 is provided between an inorganic oxide insulating layer 30 formed on a substrate 12 and the inorganic oxide insulating film 44 formed on the sealing member 48, and the sealing member 48 and the substrate 12 are bonded together. Where bonding is thus performed by also providing the inorganic oxide insulating film 44 on the side of the sealing member, at least in the portion that will come into contact with the adhesive 32, it is possible to increase the adhesive force with the adhesive 32 not only on the substrate side, but also on the side of the sealing member, the penetration of oxygen or moisture contained in the atmosphere can be prevented more reliably, and the deterioration of the light emitting device 20 can be further inhibited.

### THIRD EMBODIMENT

FIG. 6 shows schematically a cross-section of the third embodiment of the light emitting apparatus in accordance with the invention. In this light emitting apparatus 50, a cap-like sealing member (sealing cap) 52 is provided, and the edge of the sealing cap 52 is bonded via an adhesive 32 provided on an insulating layer 30 that contains an inorganic oxide and is formed around an light emitting device 20 on a substrate 12. Where such a sealing cap 52 is bonded thereto, it is possible to ensure strong bonding via the adhesive 32 provided between the sealing member 52 and the insulating layer 30 containing the inorganic oxide and located on the substrate 12, a space can be reliably provided between the sealing member 52 and the light emitting device 20, and the deterioration of the light emitting device 20 due to oxygen and moisture can be prevented more effectively by filling the space with an inert gas or inert liquid. Examples of inert gases include argon and nitrogen, and examples of inert liquids include paraffins, liquid paraffins, fluorine-containing solvents such as perfluoroalkane, perfluoroamine, and perfluoroether, chlorine-containing solvents, and silicone oils.

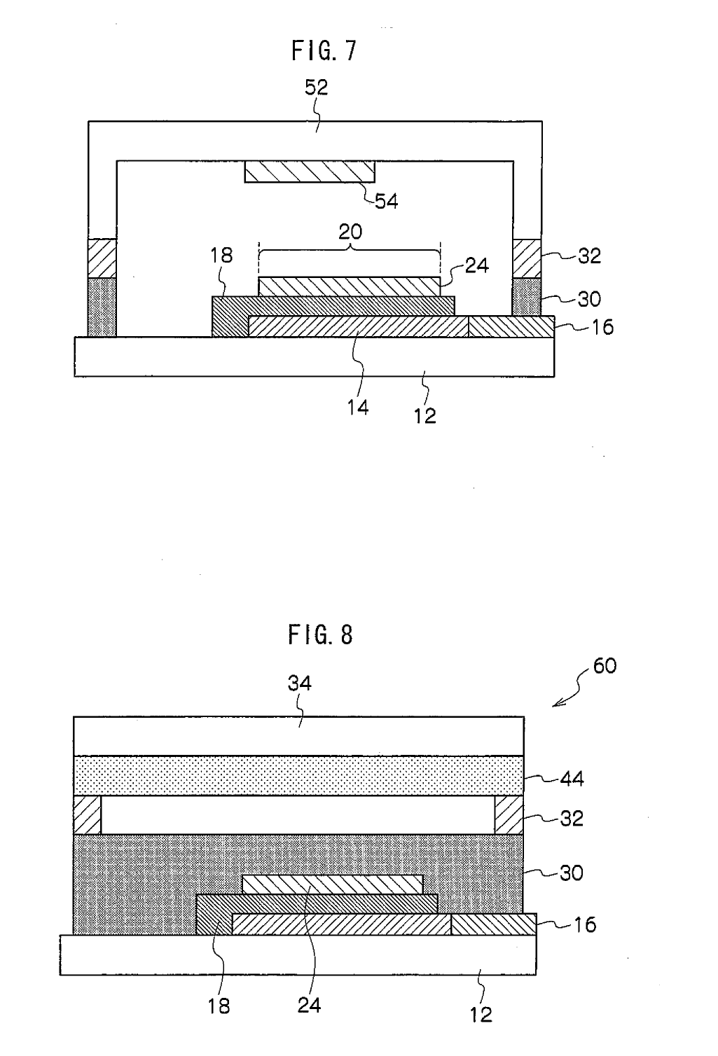

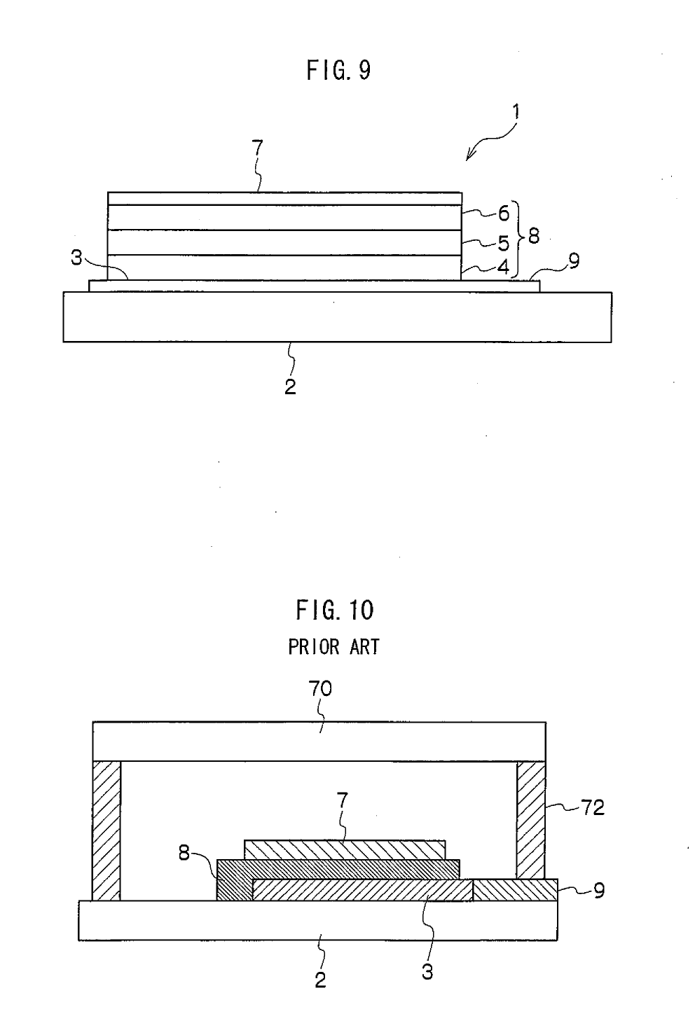

A moisture absorbent (desiccant) 54 may be enclosed in a space between the sealing cap 52 and the light emitting device 20, as shown in FIG. 7.

The moisture absorbent 54 is not particularly limited, and the examples of moisture absorbents include barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, molecular sieves, zeolites, and magnesium oxide.

With the light emitting apparatus in which the above-described moisture absorbent 54 is provided in a space between the sealing member 52 and the light emitting device 20, the sealing member 52 is strongly bonded via the adhesive 30 provided between the sealing member 52 and the insulating layer 30 containing the inorganic oxide and located on the substrate 12. Therefore, moisture penetration is made difficult, and even if a certain amount of moisture penetrates with the passage of time, it will be absorbed by the moisture absorbent 54, thereby making it possible to inhibit the deterioration of the light emitting device 20 with very high efficiency.

The invention is explained hereinabove, but the invention is not limited to the above-described embodiments. For example, as shown in FIG. 8, an insulating layer 30 containing an inorganic oxide may be formed so as to cover the entire light emitting device and the surrounding area thereof and the adhesive 32 may be provided for adhesion between the sealing member 34 and the insulating layer 30 containing the inorganic oxide that is formed around the light emitting device.

Further, the application of the light emitting apparatus in accordance with the invention is not particularly limited. For example, the light emitting apparatus of the invention can be employed in illumination devices and also in display devices such as those of television sets, personal computers, cellular phones, and electronic paper.

The foregoing description of the embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. A light emitting apparatus comprising:
a substrate;
a light emitting device having a pair of electrodes and an organic electroluminescent layer disposed between the pair of electrodes that are stacked in the thickness direction on the substrate;
lead-out lines formed on the substrate and respectively connected to the pair of electrodes of the light emitting device;
an insulating layer that contains an inorganic oxide and is formed on the substrate and on the lead-out lines and is formed around at least the light emitting device;
an adhesive provided on the insulating layer so as to surround the light emitting device; and
a sealing member that is bonded to the insulating layer via the adhesive and that seals the light emitting device.

2. The light emitting apparatus according to claim 1, further comprising an insulating layer, containing an inorganic oxide and formed at least on a portion of the sealing member that comes into contact with the adhesive.

3. The light emitting apparatus according to claim 1, wherein the sealing member comprises a plastic substrate and a barrier layer provided on the plastic substrate.

4. The light emitting apparatus according to claim 2, wherein the sealing member comprises a plastic substrate and a barrier layer provided on the plastic substrate.

5. The light emitting apparatus according to claim 1, which is a passive matrix light emitting apparatus in which the light emitting device is arranged in electrical intersections of data lines and scan lines.

6. The light emitting apparatus according to claim 2, which is a passive matrix light emitting apparatus in which the light emitting device is arranged in electrical intersections of data lines and scan lines.

7. The light emitting apparatus according to claim 3, which is a passive matrix light emitting apparatus in which the light emitting device is arranged in electrical intersections of data lines and scan lines.

8. The light emitting apparatus according to claim 4, which is a passive matrix light emitting apparatus in which the light emitting device is arranged in electrical intersections of data lines and scan lines.
